(19) United States
(12) Patent Application Publication
(10) Pub. No.: US 2026/0247888 A1
(43) Pub. Date: Aug. 20, 2026

(54) INTEGRATED MICRO AND NANOSCALE METAL ASSISTED CHEMICAL ETCH PROCESS WITH A UNIFORM AND CLEAN ETCH FRONT

(71) Applicants: Board of Regents, The University of Texas System, Austin, TX (US); Silicon Metamaterials, Inc., Austin, TX (US)

(72) Inventors: Sidlgata V. Sreenivasan, Austin, TX (US); Raul Lema Galindo, Austin, TX (US); Paras Ajay, Austin, TX (US)

(21) Appl. No.: 19/162,650

(22) PCT Filed: Mar. 8, 2024
(86) PCT No.: PCT/US2024/019047

§ 371 Date: Sep. 5, 2025

Related U.S. Application Data
(60) Provisional application No. 63/450,829, filed on Mar. 8, 2023.

(51) Int. Cl. H10P 50/64

(52) U.S. Cl. CPC H10P 50/642

(57) ABSTRACT

A method for metal assisted chemical etching. A catalyst layer is patterned on a surface of a semiconducting material, where the catalyst layer includes a pattern of sub-100 nm or less than sub-100 nm features adjacent to over 1 μm-sized features. Furthermore, the catalyst layer is multi-layered. The patterned catalyst layer is then exposed to an etchant, where the patterned catalyst layer causes etching of the semiconducting material to form nanostructures. The non-uniformity of the etch is sub-50 nm per 1 μm of etch, where the non-uniformity is enabled by the multi-layered catalyst. In this manner, simultaneous micro and nanoscale silicon etching without nanowire-like defects can be performed.

### GOVERNMENT INTERESTS

This invention was made with government support under Grant No. EEC1160494 awarded by the National Science Foundation. The government has certain rights in the invention.

### TECHNICAL FIELD

The present disclosure relates generally to metal assisted chemical etching, and more particularly to an integrated micro and nanoscale metal assisted chemical etch process with a uniform and clean etch front.

### BACKGROUND

Metal Assisted Chemical Etching (also known as MACE but referred to herein as “MacEtch”) is the process of wet chemical etching of semiconductors (mainly silicon) with the use of a metal catalyst, usually deposited on the surface of a semiconductor in the form of a thin film or nanoparticles. The semiconductor covered with the metal is then immersed in an etching solution containing an oxidizing agent and hydrofluoric acid. The metal on the surface catalyzes the reduction of the oxidizing agent and therefore in turn also the dissolution of silicon. This phenomenon of increased dissolution rate is also spatially confined, such that it is increased in close proximity to a metal particle at the surface. Eventually this leads to the formation of straight pores that are etched into the semiconductor. This means that a pre-defined pattern of the metal on the surface can be directly transferred to a semiconductor substrate.

Simultaneous micro and nanoscale etching of silicon on a wafer-scale is nowadays performed using plasma etching techniques. These plasma techniques, however, suffer from low throughput due to the Aspect-Ratio Dependent Etch (ARDE) rate, etch lag from changes in feature size, loading effects from increased etch area, and undesirable surface characteristics, such as sidewall taper and scalloping, which are particularly problematic at the nanoscale level and can affect the etch uniformity. Additionally, the hardware required for plasma etching can be very expensive. A potential alternative, which addresses the above issues with plasma etching is metal assisted chemical etching (“MacEtch”).

Unfortunately, the MacEtch process, especially an integrated micro and nanoscale MacEtch process, currently suffers from nanowire-like defects in microscale areas. As a result, the current integrated micro and nanoscale MacEtch process does not possess a uniform and clean etch front.

### SUMMARY

In one embodiment of the present disclosure, a method for metal assisted chemical etching comprises patterning a catalyst layer on a surface of a semiconducting material, where the catalyst layer comprises a pattern of sub-100 nm or less than sub-100 nm features adjacent to over 1 μm-sized features, and where the catalyst layer is multi-layered. The method further comprises exposing the patterned catalyst layer to an etchant, where the patterned catalyst layer causes etching of the semiconducting material to form nanostructures. Furthermore, a non-uniformity of the etch is sub-50 nm per 1 μm of etch, where the non-uniformity is enabled by the multi-layered catalyst.

In another embodiment of the present disclosure, a method for metal assisted chemical etching comprises patterning a substrate with lithographic structures, where a surface of the substrate is exposed in areas without the lithographic structures, and where the patterning of the substrate with lithographic structures results in sub-100 nm features adjacent to over 1 μm-sized features on the substrate. The method further comprises depositing a catalyst on the exposed substrate surface, where the catalyst is a multi-layered catalyst. The method additionally comprises exposing the deposited catalyst layer to an etchant, where the deposited catalyst layer causes etching of semiconducting material of the substrate to form nanostructures. Furthermore, non-uniformity of the etch is sub-50 nm per 1 um of etch, where the non-uniformity is enabled by the multi-layered catalyst.

The foregoing has outlined rather generally the features and technical advantages of one or more embodiments of the present invention in order that the detailed description of the present invention that follows may be better understood. Additional features and advantages of the present invention will be described hereinafter which may form the subject of the claims of the present invention.

### BRIEF DESCRIPTION OF THE DRAWINGS

A better understanding of the present invention can be obtained when the following detailed description is considered in conjunction with the following drawings, in which:

FIGS. 1A-1I illustrate a microscale MacEtch on an oxide-free silicon substrate with a 3 nm Ag and 15 nm Au catalyst stack and a 12.5/1 M/M etchant, where photoresist lift-off was performed right before etching in accordance with an embodiment of the present disclosure;

FIGS. 2A-2I illustrate a microscale MacEtch on an oxide-free silicon substrate with a 3 nm Ag and 15 nm Au catalyst stack and a 8.44/0.5 M/M etchant, where photoresist lift-off was performed right before etching in accordance with an embodiment of the present disclosure;

FIGS. 3A-3I illustrate a microscale MacEtch on an oxide-free silicon substrate with a 3 nm Ag and 15 nm Au catalyst stack and a 12.5/1 M/M etchant, where no photoresist lift-off was performed before etching in accordance with an embodiment of the present disclosure;

FIGS. 4A-4I illustrate a microscale MacEtch on an oxide-free silicon substrate with a 3 nm Ag and 15 nm Au catalyst stack and a 8.44/0.5 M/M etchant, where no photoresist lift-off was performed before etching in accordance with an embodiment of the present disclosure;

FIGS. 5A-5F illustrate nanoscale etching on an oxide-free silicon substrate with a 3 nm Ag and 15 nm Au catalyst stack in accordance with an embodiment of the present disclosure; and

FIGS. 6A-6E illustrate integrated micro- and nanoscale MacEtch results on an oxide-free silicon substrate with a 3 nm Ag and 15 nm Au catalyst stack and an 8.44/05 M/M etchant in accordance with an embodiment of the present disclosure.

### DETAILED DESCRIPTION

As stated above, Metal Assisted Chemical Etching (also known as MACE but referred to herein as “MacEtch”) is the process of wet chemical etching of semiconductors (mainly silicon) with the use of a metal catalyst, usually deposited on the surface of a semiconductor in the form of a thin film or nanoparticles. The semiconductor covered with the metal is then immersed in an etching solution containing an oxidizing agent and hydrofluoric acid. The metal on the surface catalyzes the reduction of the oxidizing agent and therefore in turn also the dissolution of silicon. This phenomenon of increased dissolution rate is also spatially confined, such that it is increased in close proximity to a metal particle at the surface. Eventually this leads to the formation of straight pores that are etched into the semiconductor. This means that a pre-defined pattern of the metal on the surface can be directly transferred to a semiconductor substrate.

Simultaneous micro and nanoscale etching of silicon on a wafer-scale is nowadays performed using plasma etching techniques. These plasma techniques, however, suffer from low throughput due to the Aspect-Ratio Dependent Etch (ARDE) rate, etch lag from changes in feature size, loading effects from increased etch area, and undesirable surface characteristics, such as sidewall taper and scalloping, which are particularly problematic at the nanoscale level and can affect the etch uniformity. Additionally, the hardware required for plasma etching can be very expensive. A potential alternative, which addresses the above issues with plasma etching is metal assisted chemical etching (“MacEtch”).

Unfortunately, the MacEtch process, especially an integrated micro and nanoscale MacEtch process, currently suffers from nanowire-like defects in microscale areas. As a result, the current integrated micro and nanoscale MacEtch process does not possess a uniform and clean etch front.

As discussed herein, the principles of the present disclosure provide a feasible process flow for simultaneous micro and nanoscale silicon etching without nanowire-like defects, which is referred to herein as the “Integrated Micro- and Nanoscale MacEtch” (IMN-MacEtch). Successful etching of silicon features ranging from 100 nm to 100 μm was achieved using embodiments of the present disclosure as discussed herein with etch rates of about 1.8 μm/min in a single step to achieve features with an Aspect Ratio (AR) ~18:1. As a result, embodiments of the present disclosure provide a feasible alternative to current dry etch methods for patterning feature sizes spanning three orders of magnitude.

In one embodiment, a catalyst layer is patterned on a surface of the semiconducting material, where the catalyst layer includes a pattern of sub-100 nm or less than sub-100 nm (e.g., 50 nm) features that are adjacent to over 1 μm-sized features, including those features over 10 μm, 100 μm, etc.

Furthermore, in one embodiment, such a catalyst layer is a multi-layered catalyst. In one embodiment, such a catalyst includes a bilayer of silver and gold. In one embodiment, the thickness of the silver is around 3 nm, and the thickness of the gold is around 11 nm.

Additionally, in one embodiment, the catalyst layer includes a pattern of adjacent features that are different in their sizes by three-orders of magnitude.

Furthermore, in one embodiment, the patterned catalyst layer is exposed to an etchant. In one embodiment, the etchant includes a concentration of HF between 5 and 10M as well as a concentration of H₂O₂ between 0.4 and 0.6M. In one embodiment, the etchant includes a concentration of HF of 8.4M as well as a concentration of H₂O₂ of 0.5M.

In one embodiment, a substrate is patterned with lithographic structures, where a surface of the substrate is exposed in areas without lithographic structures. In one embodiment, the patterning of the substrate with lithographic structures results in sub-100 nm features adjacent to features exceeding 1 μm in size on the substrate.

In one embodiment, a catalyst is deposited on the exposed substrate surface, where the catalyst is a multi-layered catalyst. In one embodiment, the deposited catalyst layer is exposed to an etchant, where the deposited catalyst layer causes etching of semiconducting material of the substrate to form nanostructures.

In one embodiment, the non-uniformity of the etch is sub-50 nm per 1 μm of etch, where the non-uniformity is enabled by the multi-layered catalyst.

A brief discussion regarding MacEtch is provided below.

Similar to dry plasma etch techniques, MacEtch is also suitable for etching at both the micro and nanoscales. At the nanoscale, MacEtch has been used to create nanopillars, pores, and trenches and etch rates between ~1 μm/min and ~4 μm/min, with local etch rates of approximately 8.6 μm/min achievable in some cases, although etch rates below 1 μm/min are possible. Wafer-scale nanopatterned substrates are also compatible with light-scattering-based metrology, which had been previously developed for plasma-etched silicon substrates. At the microscale, an etch rate of ~2.8 μm/min for hole formation has been reported with the use of an added electric bias to assist in the etch process, which is faster than the etch rate obtained for hole formation with a BOSCH™ process. As far as pillar formation, however, catalyst instability limits etch quality, and etch rates below 0.5 μm/min using MacEtch fail to outperform even Cryo-RIE, where micropillars are etched at ~0.96 μm/min. An alternative implementation of MacEtch relies on the use of HF in the gaseous state though the etch rates are also below 1 μm/min.

Currently, MacEtch is mainly utilized to etch features on a single scale. As discussed above, there is currently no integration of micro and nanoscale MacEtch without the incidence of nanowire-type defects in microscale areas, where these multiscale features are an intrinsic part of the device, as could be the case for microfluidic devices for nanoparticle separation or zone plates.

An example of a current multiscale etch process uses a HF-vapor-based process for zone plate fabrication. Although such a process achieves high (82:1) multiscale AR and ultra-high (10,000:1) nanoscale AR, their etch quality at the multiscale is negatively impacted by the presence of widespread nanowire-type defects due to metal layer porosity—which is needed for adequate large-scale etching. Additionally, such a process suffers from a very slow etch rate (~0.4 μm/min). Lastly, this etch technique requires appropriate temperature control to prevent condensation and a high-temperature anneal to improve catalyst stability, which adds both complexity and sample manipulation requirements to the process.

The embodiments of the present disclosure address such deficiencies by developing a feasible approach for scalable integrated micro-nanoscale MacEtch, which is referred to herein as the “IMN-MacEtch,” at room temperature and in liquid solution. For example, an embodiment of the present disclosure utilizes Jet-and-Flash Imprint Lithography (J-FIL) and an Ag/Au catalyst bilayer which allows for simultaneous etching of 100 nm (200 nm pitch) nanopillars and 50 μm to 100 μm streets at a rate of ~1.8 μm/min, approximately 5 times faster than current techniques, and without widespread nanowhisker defects in the microscale etch areas. The samples using the techniques of the present disclosure achieve an AR of ~18:1 without significant catalyst instability. Hence, embodiments of the present disclosure provide a feasible option for high-throughput fabrication of silicon devices. A discussion regarding the materials used by embodiments of the present disclosure to achieve a scalable integrated micro-nanoscale MacEtch is discussed below.

In one embodiment, an experiment was performed using substrates that were single-crystal, 100 mm, P-type, low-doped (1-10 Ω-cm), <100>, 500 μm-thick silicon wafers, which were supplied by: Nova Electronic Materials for nanopatterning and thermal oxide experiments, University Wafer for micropatterning experiments, and Pure Wafer for integrated micro-nano experiments. The adhesion layer (TranSpin) used to coat the wafers before micro- and nanopatterning was provided by Canon® Nanotechnologies Inc. Nanopatterning and integrated micro-nanoscale patterning was done with a proprietary polymer provided by Canon® Nanotechnologies Inc. Micropatterning experiments were performed using AZ-5209E positive tone photoresist and AZ 1:1 developer (MicroChemicals).

With respect to substrate preparation, when required, a solution consisting of a 2:1 mixture of 96% v/v Sulfuric Acid (H₂SO₄) and 30% v/v Hydrogen Peroxide (H₂O₂) prepared in a quartz tank for 10 minutes was used. The substrates were then dipped in 49% v/v Hydrofluoric Acid (HF) for 30 seconds to remove the surface oxide unless otherwise noted. Next, the TranSpin adhesion layer was spin coated at 4000 RPM for 60 seconds and baked on a hot plate at 165° C. for 70 seconds. The wafers were air-cooled with a nitrogen gun and patterned. For micropatterning, a ~900 nm layer of photoresist was deposited using a spin-coater at 4000 RPM for 60 seconds and baked at 90° C. for 2 minutes.

With respect to substrate patterning, an Imprio 1100 Jet-and-Flash nanoimprint Lithography (J-FIL) tool (Molecular Imprints, Inc.) with an imprint template consisting of 100 nm pillars with 200 nm pitch in 1×1 mm² blocks separated by 100 μm trenches was used for nanopatterning. Micropatterning, on the other hand, consisted of hard-contact lithography using an acrylic clamp made in-house and a mylar photomask provided by CAD/Art Services Inc. based on a repeating grid of micropillars with 10 μm to 50 μm diameters and 20 μm gap.

The UV exposure was done inside an IntelliRay 400 W UV flood lamp for 12 seconds. Then a 40 second development step and water quench were performed before a thorough rinsing in a Spin-Rinse-Dry (SRD) tool.

Following both micro and nanopatterning, a residual layer from imprint resist, photoresist, and an adhesion layer was left between the pillars such that the silicon substrate was not exposed. This residual layer was removed using a Reactive Ion Etch tool (Oxford Instruments®) with a plasma-based polymer etch recipe consisting of a 5 sccm O₂ and 70 sccm Ar gas flow mix with a 65 W plasma inside a chamber at 15 mTorr pressure for 55 seconds for J-FIL defined patterns and 3 minutes for photolithography defined patterns. An optional photoresist lift-off step was performed after metal deposition for some micropatterned samples prior to wet etch of the silicon.

With respect to metal layer deposition, the metal-catalyst deposition was performed using a physical vapor deposition electron-beam evaporator (CHA Industries®) under high vacuum (5×10⁻⁶ Torr). The deposition rate for each metal was 0.2 Å/s for Ag, and 0.4 Å/s for Au. When attempted, Ti was deposited at a rate of 0.2 Å/s.

The following discusses the step of performing a metal-assisted chemical etch.

Following metal catalyst deposition, or lift-off (if applicable), the substrates were placed in a solution consisting of HF, H₂O₂ and DI-water. Two different etchant chemistries were tested: a 12.5/1 M/M ([HF]/[H₂O₂]) solution (4:1:4 HF:H₂O₂:H₂O volume ratios) and a 8.44/0.5 M/M solution (6:1:13 HF:H₂O₂:H₂O volume ratios). Etch times were: 30 seconds in 12.5/1 M/M and 60 seconds in 8.44/0.4 M/M for nanopatterned samples, and 10 minutes regardless of etchant chemistry for micropatterned samples. Following the etch, all samples were quenched in a DI H₂O bath and thoroughly rinsed and dried using clean, dry air (CDA).

The results obtained from performing the experiments discussed above are divided into three subsets: micropillar etching, nanopillar etching, and micro-nanoscale etching. The first two subsets were performed as part of a larger experimental space exploration to identify feasible process parameters for multiscale etching, some of which are repeated here. Briefly, the micro and nanoscale etching results originate from a set of 54 individual experiments aimed at identifying the adequate metal stack, substrate surface oxide thickness, and etching solution composition. The micro-nanoscale etching conditions were performed from further optimizing the metal stack and selecting the substrate conditions and etchant concentration identified to be the best possible for micro and nanoscale patterning. A summary of the results presented here is shown in Table 1. For all experiments, the etchant is presented as the ratio of HF to H₂O₂ molar concentration ([HF]/[H₂O₂] M/M).

TABLE 1
Summary of etch results for micro, nano, and multiscale patterning. For Experiment
name, M = Microscale, N = Nanoscale, MB = Metal-Break, LO =
Lift-off, IMN = Integrated Micro-Nanoscale, High = 12.5/1 M/M etchant
used, Low = 8.44/0.5 M/M etchant used. All microscale samples were etched
for 10 minutes. Nanoscale samples with 12.5/1 (8.44/0.5) M/M solution were etched
for 30 (60) seconds. IMN sample was etched for 60 seconds.

| | Catalyst | | | | | | | | |
|---|---|---|---|---|---|---|---|---|---|
| | Thickness | | | | | | Etch Rate | | |
| | Ag/Au | HF/H₂O₂ | Etch Depth [μm] | | | | [μm/min] | | Data |
| Exp. | [nm/nm] | [M/M] | Mean^{a} | S.D.^{a} | Min | Max | Mean^{b} | S.D.^{b} | Points |
| M_LO_High | 3/15 | 12.5/1 | 12.069 | 0.994 | 8.613 | 13.496 | 1.207 | 0.099 | 38 |
| M_LO_Low | 3/15 | 8.44/0.5 | 3.458 | 0.347 | 2.928 | 4.334 | 0.346 | 0.035 | 38 |
| M_MB_High | 3/15 | 12.5/1 | 14.925 | 0.991 | 12.209 | 18.256 | 1.493 | 0.099 | 52 |
| M_MB_Low | 3/15 | 8.44/0.5 | 7.562 | 0.560 | 6.690 | 8.759 | 0.756 | 0.056 | 74 |
| N_High | 3/15 | 12.5/1 | 1.459 | 0.199 | 0.921 | 1.821 | 2.918 | 0.398 | 163 |
| N_Low | 3/15 | 8.44/0.5 | 1.112 | 0.261 | 0.471 | 1.465 | 1.112 | 0.261 | 113 |
| IMN | 3/11 | 8.44/0.5 | 1.793 | 0.127 | 1.264 | 2.069 | 1.793 | 0.127 | 211 |

Micropillar etching results are divided in two conditions: (i) a “metal-break” process where the metal catalyst breaks around the photoresists caps, similar to the J-FIL MacEtch process, and (ii) a photoresist lift-off process.

The following discusses lift-off micropillar etching.

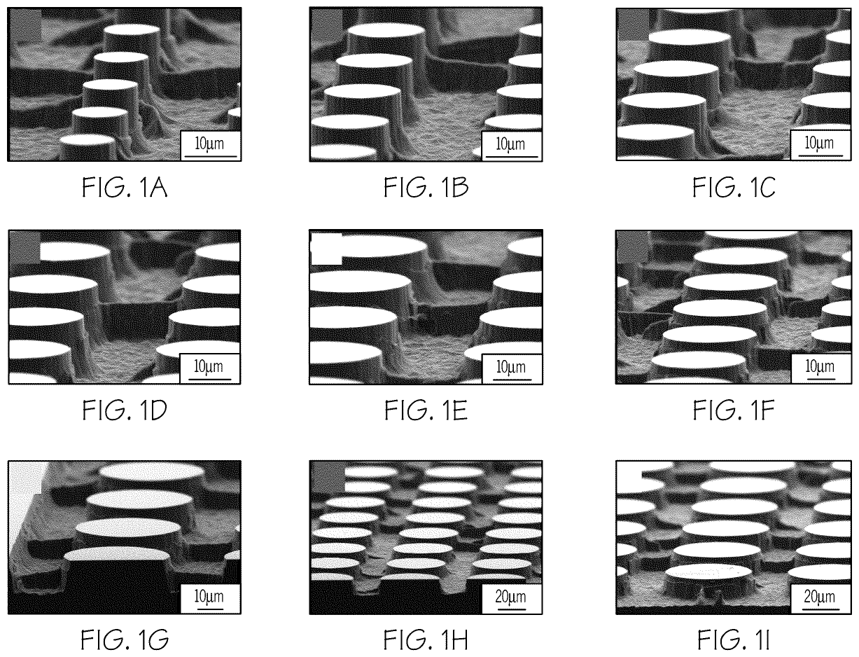

The results obtained with the 12.5/1 M/M solution are presented in FIGS. 1A-1I. FIGS. 1A-1I illustrate a microscale MacEtch on an oxide-free silicon substrate with a 3 nm Ag and 15 nm Au catalyst stack and a 12.5/1 M/M etchant, where photoresist lift-off was performed right before etching in accordance with an embodiment of the present disclosure. FIG. 1A illustrates 10 μm pillars. FIG. 1B illustrates 15 μm pillars. FIG. 1C illustrates 20 μm pillars. FIG. 1D illustrates 25 μm pillars. FIG. 1E illustrates 30 μm pillars. FIG. 1F illustrates 35 μm pillars. FIG. 1G illustrates 40 μm pillars. FIG. 1H illustrates 45 μm pillars. FIG. 1I illustrates 50 μm pillars.

Metal catalyst cracking and fin formation can be observed between the pillars, with some widening of features observed as the etch progressed, as well as some collapsed nanowires, which could have resulted from porosity in the catalyst. Pillar height and etch rate across the sample was found to be 12.069 (0.994) μm, and 1.207 (0.099) μm/min, respectively. The range between the tallest and shortest pillars was found to be ~4.9 μm.

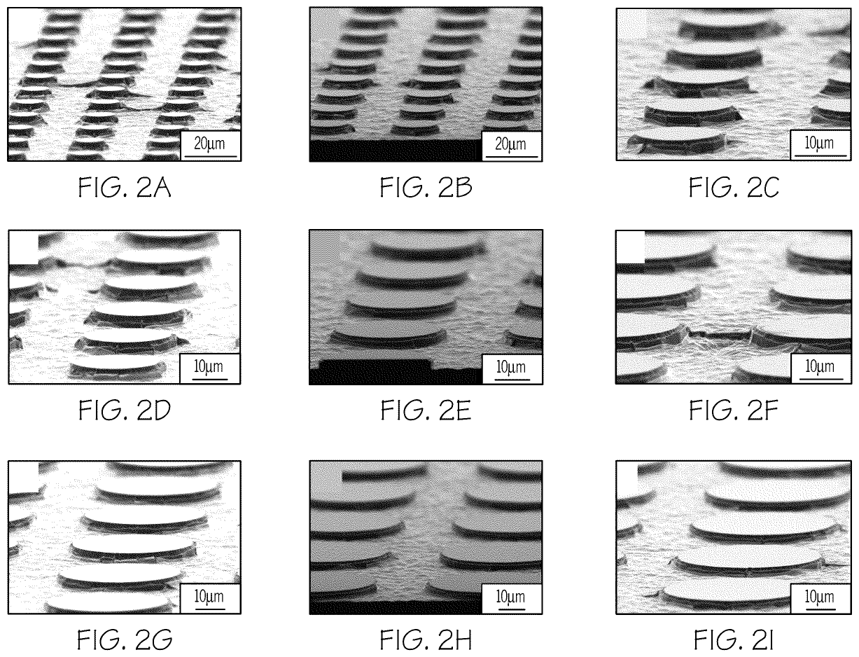

Using the 8.44/0.5 M/M etchant instead caused a large decrease in the etch, such as a slower hole injection rate into the silicon and a slower oxide removal. The resulting micropillars are shown in FIGS. 2A-2I. FIGS. 2A-2I illustrate a microscale MacEtch on an oxide-free silicon substrate with a 3 nm Ag and 15 nm Au catalyst stack and a 8.44/0.5 M/M etchant, where photoresist lift-off was performed right before etching in accordance with an embodiment of the present disclosure. FIG. 2A illustrates 10 μm pillars. FIG. 2B illustrates 15 μm pillars. FIG. 2C illustrates 20 μm pillars. FIG. 2D illustrates 25 μm pillars. FIG. 2E illustrates 30 μm pillars. FIG. 2F illustrates 35 μm pillars. FIG. 2G illustrates 40 μm pillars. FIG. 2H illustrates 45 μm pillars. FIG. 2I illustrates 50 μm pillars.

The catalyst stability seems improved as no large fins are visible, but some catalyst breaks are still observed (e.g., FIGS. 2A and 2F). The measured etch depth was 3.458 (0.347) μm for an etch rate of 0.346 (0.035) μm/min. The pillar height range was found to be ~1.4 μm.

The following discusses metal-break micropillar etching.

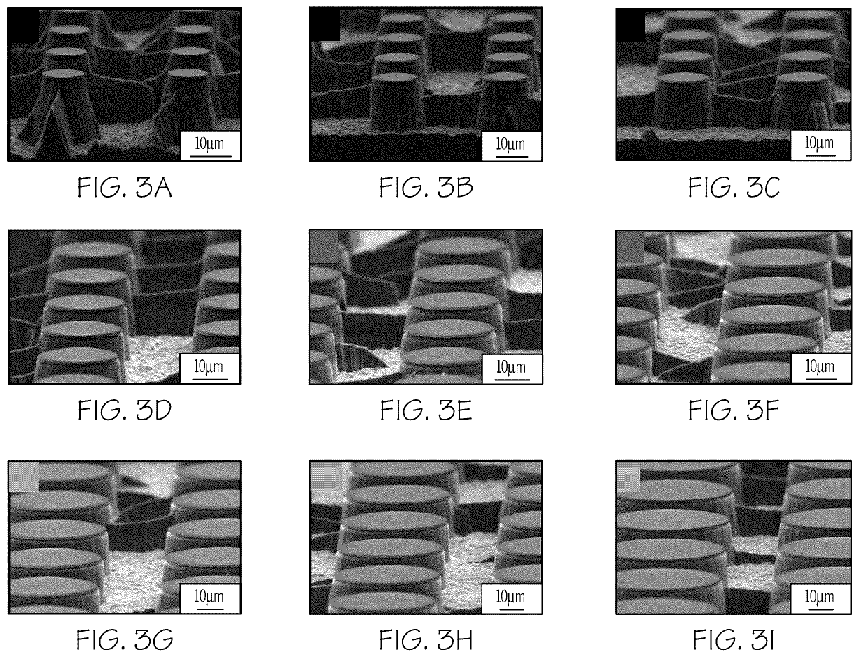

Referring to FIGS. 3A-3I, FIGS. 3A-3I illustrate a microscale MacEtch on an oxide-free silicon substrate with a 3 nm Ag and 15 nm Au catalyst stack and a 12.5/1 M/M etchant, where no photoresist lift-off was performed before etching in accordance with an embodiment of the present disclosure. FIG. 3A illustrates 10 μm pillars. FIG. 3B illustrates 15 μm pillars. FIG. 3C illustrates 20 μm pillars. FIG. 3D illustrates 25 μm pillars. FIG. 3E illustrates 30 μm pillars. FIG. 3F illustrates 35 μm pillars. FIG. 3G illustrates 40 μm pillars. FIG. 3H illustrates 45 μm pillars. FIG. 3I illustrates 50 μm pillars.

FIGS. 3A-3I show the results obtained using the 12.5/1 M/M etchant on the metal-break sample. The etch depth achieved across all 9 regions was 14.925 (0.991) μm, with an etch rate of 1.493 (0.099) μm/min, or nearly five times faster than the results obtained with a similar metal stack but different etchant solution. Large fins resulting from catalyst instability can be observed as well as non-vertical sidewalls particularly for thinner pillars (e.g., FIG. 3A). Etch non-uniformity could be observed with the bottom of the etched area showing irregular topography, and some porosity formation at the tops of the features was also evident. The height range for pillars across the sample was ~6 μm.

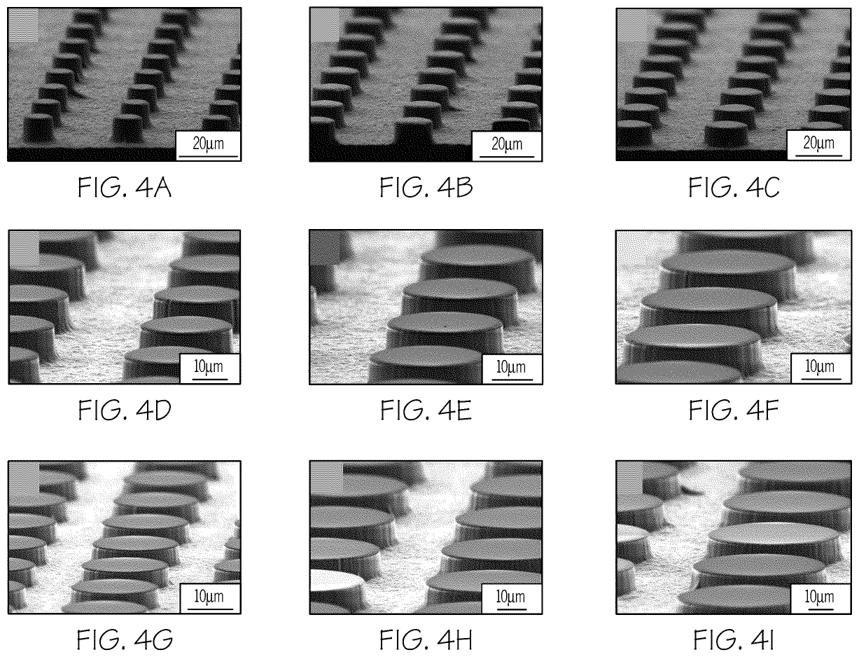

Decreasing the etchant concentrations to 8.44/0.5 M/M etchant addressed the tapering and catalyst break issues seen in FIGS. 3A-3I. This improved etch quality is shown in FIGS. 4A-4I.

FIGS. 4A-4I illustrate a microscale MacEtch on an oxide-free silicon substrate with a 3 nm Ag and 15 nm Au catalyst stack and a 8.44/0.5 M/M etchant, where no photoresist lift-off was performed before etching in accordance with an embodiment of the present disclosure. FIG. 4A illustrates 10 μm pillars. FIG. 4B illustrates 15 μm pillars. FIG. 4C illustrates 20 μm pillars. FIG. 4D illustrates 25 μm pillars. FIG. 4E illustrates 30 μm pillars. FIG. 4F illustrates 35 μm pillars. FIG. 4G illustrates 40 μm pillars. FIG. 4H illustrates 45 μm pillars. FIG. 4I illustrates 50 μm pillars.

The etch depth was measured to be 7.562 (0.560) μm, for an etch rate of 0.756 (0.056) μm/min, about 2.5 times faster than prior techniques, and with very similar etch conditions. Etch uniformity also improved as seen by an apparent smoother surface at the bottom of the pillars. The pillar height range was ~2.1 μm.

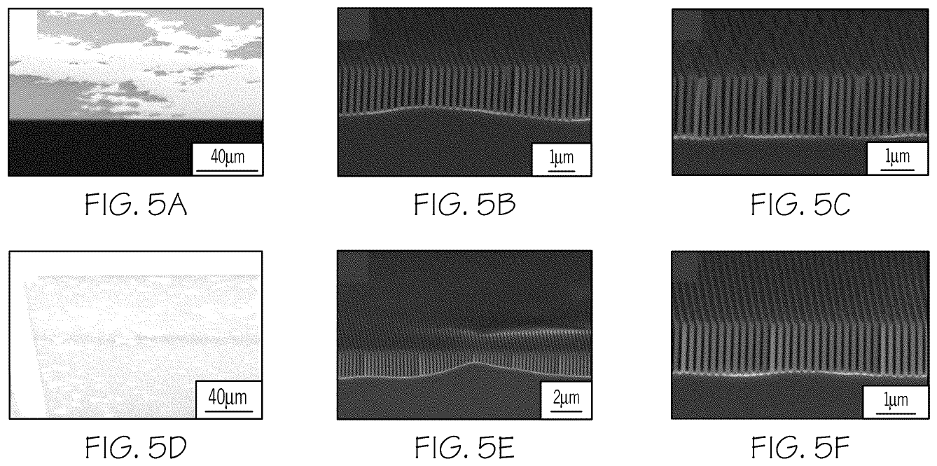

The nanopillar etch results for both etchant concentrations are shown in FIGS. 5A-5F.

FIGS. 5A-5F illustrate nanoscale etching on an oxide-free silicon substrate with a 3 nm Ag and 15 nm Au catalyst stack in accordance with an embodiment of the present disclosure. FIGS. 5A-5C illustrate etching in the 12.5/1 M/M solution. FIGS. 5D-5F illustrate etching in the 8.44/0.5 M/M solution.

Some non-uniform etching was observed, particularly in FIGS. 5A and 5D, with local etch non-uniformities shown in FIGS. 5B and 5E. The source for this non-uniform etching may be due to incomplete residual layer removal as discussed further below. Evidence of collapse is seen in FIG. 5C. The pillar heights accomplished were 1.459 (0.199) μm and 1.112 (0.261) μm for the 12.5/1 M/M and 8.44/0.5 M/M etchants, which corresponded to etch rates of 2.918 (0.398) μm/min and 1.112 (0.261) μm/min, and AR ~12:1 and ~9:1, respectively. The pillar height range was ~0.9 μm for the 12.5/1 M/M etchant, and ~1 μm for the 8.44/0.5 M/M etchant.

The following discusses integrated micro-nanoscale etching (IMN-MacEtch).

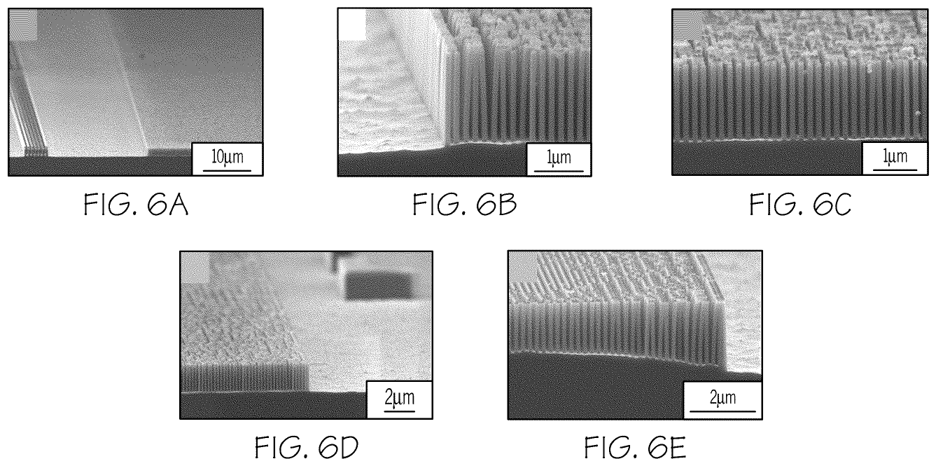

Based on the results presented above, integrated micro and nanoscale etching was performed using the 8.44/0.5 M/M etchant and an optimized metal stack, as explained below. The results for multiscale etching are shown in FIGS. 6A-6E.

FIGS. 6A-6E illustrate integrated micro- and nanoscale MacEtch results on an oxide-free silicon substrate with a 3 nm Ag and 15 nm Au catalyst stack and an 8.44/05 M/M etchant in accordance with an embodiment of the present disclosure. FIG. 6A illustrates the nanopillar array at 10 μm. FIGS. 6B-6C illustrate the nanopillar array at 1 μm. FIGS. 6D-6E illustrate the nanopillar array at 2 μm. Evidence of etch non-uniformity at the edge of the nanopillar array is show in FIG. 6E.

The optimal metal stack was found to be 3 nm Ag and 11 nm Au, instead of the 15 nm Au used for the results presented previously. For this multiscale etch, the pillar height was 1.793 (0.127) μm, with an etch rate of 1.793 (0.127) μm/min.

Some areas of localized etch non-uniformity occurred as shown in FIG. 6E, which was accounted for in the calculation of the standard deviation in height. Other regions appeared to be dominated by pinhole rather than uniform etching, or localized metal layer defects causing island structures to form in the microscale areas.

The reason for these defects could be attributed to non-uniform residual layer removal or non-uniform catalyst thickness. Since these defects could be optimized for and reduced, the areas with pinhole etching were not taken into account when measuring pillar height. Large areas were observed to be defect-free, however, giving credence to the conclusion that, uniform, and multiscale etch was obtained for the first time, where 100 nm-diameter pillars with 200 nm pitch and 50 μm to 100 μm trenches with microscale features were etched simultaneously.

Catalyst selection is a valuable step in developing a feasible MacEtch process. The catalyst needs to be chosen such that the correct potential difference exists between the metal and silicon surface to ensure the reaction can proceed. Furthermore, it is important to consider that different catalysts will exhibit different catalytic activity, that catalyst bilayers may exhibit improved catalytic activity than a single metal layer and that different bilayers will lead to differences in etch quality. As discussed herein, three catalyst compositions, namely, Ti/Au, Ti/Ag/Au, and Ag/Au, were considered.

With respect to utilizing a Ti/Au catalyst bilayer, in one embodiment, the implementation of a Ti/Au catalyst involved using a thick Au layer (~40 nm) and low temperature etching, which resulted in very slow etching (~0.1 μm/min). This low etch rate would be undesirable for high throughput etching. The experiments performed on substrates similar to those used for individual micro and nanopatterning experiments showed that using a 0.5 nm Ti and 15 nm Au catalyst resulted in uniform etching at the nanoscale for both etchants but failed to produce micropillars regardless of pre-etch treatment of the samples.

With respect to the Ti/Ag/Au tri-layer, a stack consisting of 0.5 nm Ti, 3 nm Ag and 15 nm Au was tested. This stack failed to produce high quality etch results at both micro and nanoscales.

The failure was somewhat unexpected as Ti was only used as an adhesion layer which acts as an etch delay that needs to dissolve before the etch can progress in MacEtch. The use of a metal tri-layer, however, was discarded as a feasible catalyst for these substrates.

Lastly, a thin Ag and thick Au catalyst was utilized which yielded successful etching at both the micro and nanoscales, as previously discussed. Furthermore, the etch rate for Ag/Au-MacEtch at the nanoscale was higher than the etch rate obtained for the Ti/Au catalyst for either etchant concentration. The etch rates for the Ag/Au catalyst were 2.918 (0.398) μm/min and 1.112 (0.261) μm/min, whereas the etch rates for the Ti/Au catalyst as shown in Table 2 below were 1.573 (0.075) μm/min and 0.673 (0.0085) μm/min for the 12.5/1 M/M and 8.44/0.5 M/M etchants, respectively.

TABLE 2
Nanopatterning etch results for different oxide conditions with an Ag/Au catalyst.

| | | | | | | | | | Etch Rate | |
|---|---|---|---|---|---|---|---|---|---|---|
| | Surface | Metal | HF/H₂O₂ | Time | Etch Depth [μm] | | | | [μm/min] | |
| Exp. | Oxide | Stack | [M/M] | [min] | Mean | S.D. | Min | Max | Mean | S.D. |
| Uniform | Native | Ag/Au | 8.44/0.5 | 1 | 1.368 | 0.076 | 1.140 | 1.528 | 1.368 | 0.076 |
| | Oxide | | | | | | | | | |
| Non- | Thermal | Ag/Au | 12.5/1 | 0.5 | 1.832 | 0.182 | 1.237 | 2.165 | 3.664 | 0.364 |
| Uniform | Oxide | | | | | | | | | |
| Non- | Thermal | Ag/Au | 8.44/0.5 | 1 | 1.339 | 0.127 | 0.937 | 1.558 | 1.339 | 0.127 |
| Uniform | Oxide | | | | | | | | | |

These differences in etch rate appear to be statistically significant for the 12.1/1 M/M etchant but not for the 8.44/0.5 M/M case as the 3-σ confidence interval (CI) of the former is [1.724, 4.112] μm/min, which does not include the mean etch rate for the Ti/Au case, but the 3-σ CI of the latter is [0.329, 1.895] μm/min, which does encompass the mean etch rate for the 8.44/0.5 M/M Ti/Au case. It should be noted, however, that the incidence of defects for the Ag/Au-catalyzed case, shown in FIGS. 5A-5F, led to the large standard deviations in etch rates for this case compared to the more uniform etch obtained with the Ti/Au catalyst.

These defects are hypothesized to be due to incomplete residual layer removal and surface defects, contaminants, or variations in metal thickness causing localized areas of conformal metal layer formation. Both of these defects would inhibit MacEtch locally. Localized incomplete residual layer removal, or contaminants affecting pattern definition and imprint resist spreading and thickness are more likely the reason for non-uniform etch, since no reason for metal thickness variation is readily apparent given the equipment used for metal deposition. In any case, these issues result from external factors that cannot be easily controlled and represent non-repeatable sources of error. Regarding incomplete residual layer removal, potential causes could be plasma uniformity in the etch chamber, whereas surface contamination could result from manual handling and transport of the samples or contaminants present on the nanoimprint template. The residual layer could also be affected by issues with the inkjet that dispenses the imprint resist on the substrate for J-FIL, which could cause thickness variation in the residual layer. Although these issues are non-repeatable and difficult to predict, some steps could be taken to resolve or mitigate them. First, residual layer removal can be improved by increasing the plasma etch time before metal deposition, but a limit exists in which the polymer features would be negatively impacted. Next, recurrent cleaning of the imprint template and careful manipulation of the template and sample can decrease the incidence of surface contaminants, although particle contamination can never be fully prevented in a laboratory setting where human intervention is involved.

A final, but important, remark regarding the choice of catalyst, is the observed instability of Ag in MacEtch, which could lead to dissolution and re-deposition of silver causing defects. This dissolution and re-deposition behavior is shown to depend on the etchant concentration ratio. No Ag instability would have been expected for the catalyst concentrations used. Silicon erosion is seen, however, particularly at the tops of micropillars etched in the 12.5/1 M/M solution with a metal-break approach to etch. This dissolution might have been mitigated by the addition of an Au layer on top. Also, the addition of HCl may help improve silver-instability issues.

A discussion regarding substrate treatment is provided below.

As stated above, the samples used to obtain the results discussed herein were pre-treated with HF to remove any surface oxide present prior to photopatterning or J-FIL. It is noted that the silicon surface begins to oxidize immediately upon exposure to room temperature air. Thus, these samples were not truly oxide-free, but instead had a surface oxide thickness less than native silicon oxide. To compare the etch results with different oxide conditions, native oxide and 25 nm-thermal oxide substrates were also etched using the Ag/Au catalyst. On samples with a native oxide, nanopillar etching with the 8.44/0.5 M/M etchant and metal-break micropillar etching with the 12.5/1 M/M etchant were the only cases that yielded potentially useful results.

At the microscale, metal-break etching with the 12.5/1 M/M etchant for 10 minutes on a native oxide substrate yielded good results. No significant defects in the etch front are observed. Furthermore, some bowing and pillar top erosion was also observed.

The mismatched etchant, however, meant that further exploration was disregarded. Thermal-oxide samples only yielded satisfactory results at the nanoscale, though similar issues with etch uniformity were present as in the oxide-free case.

No microscale etching could be achieved with an Ag/Au catalyst on 25 nm-oxide samples. The reason for why oxide layers cause different results is not readily apparent.

As for 25 nm-thermal oxide samples, catalyst delamination can be observed for the 12.5/1 M/M sample and photoresist lift-off can be observed for both etchant concentrations. The catalyst delamination may have been caused by the underlying oxide being fully etched away and leading to a large gap with the metal such that attractive forces to silicon were too low for contact to be re-established. Photoresist lift-off could be caused by removal of the oxide layer as well.

A potential reason for the influence of oxide could be that it provides a uniform starting point for the etch reaction where HF first removes all oxide present before the catalyst is in contact with silicon. Since the catalyst has to sink, this may improve the metal-break around the polymer pattern caps by breaking the catalyst in areas where the layer would otherwise be conformal. This may be more noticeable with a thick thermal oxide rather than native oxide which tends to be <5 nm thick. Furthermore, thermal oxide may have a more uniform surface topology than native oxide does.

A discussion regarding etchant concertation is provided below.

The concentration of chemical species in the etchant has an impact on the etch rate and feature quality for the silicon micro and nanostructures as well as potentially affect stress evolution on the metal film. Increasing peroxide is shown to increase the etch rate, but too much peroxide can cause the hole injection to exceed the rate of oxide consumption and lead to hole diffusion which then causes porosity and lateral etching. Lateral etching and porosity formation can be problematic when attempting to etch deep-vertical trenches or microscale features. Increased peroxide concentration can also lead to uncontrolled dissolution of silver, which could greatly impact the etch quality given the Ag/Au catalyst bilayer. Too much HF could lead to stress accumulation on the film, but it can be used to address porosity and sidewall tapering. Additionally, the relative concentration of the chemical species may impact the etch regime and thus the results.

The results from the experiments discussed herein indicated an increased etch rate for the higher concentration of chemical species and also showed that whenever the etch rate was slower, better etch quality was obtained. The etch rate reduction between the 12.5/1 and 8.44/0.5 M/M solutions was ~71%, ~49% and ~62% for the lift-off microscale, metal-break microscale and nanoscale etching samples, respectively. For microscale samples presented in FIGS. 1A-1I, 2A-21, 3A-3I, and 4A-4I, the decrease in etch rate led to successful prevention of catalyst failure, which would result in prominent fin formation (see FIGS. 1A-1I and 3A-3I), though some instability was still occasionally seen with the weaker etchant. In the case of lift-off samples (see FIGS. 2A-2I), however, some of the catalyst damage may have been induced by the ultrasonication step for resist removal. The improved catalyst stability for a slower etch rate can be attributed to the slowing of the hole injection to better match the oxide removal rate, and to an overall slower reaction allowing for more uniform removal of material across the entire etch area even for large lateral dimensions. If the material removal is more uniform, then the strain accumulation on the film will not reach a critical magnitude that enables crack formation and propagation.

A discussion regarding lift-off versus metal-break is provided below.

When comparing the lift-off versus the metal-break approach, it is apparent that lift-off has some advantages. In particular, from the 12.5/1 M/M etch results following lift-off, a ~90° angle with no visible erosion or porosity forms at the top of the micropillar features (see FIGS. 1A-1I), whereas the metal-break sample etched under the same conditions resulted in visible porosity and rounding at the top of the silicon features, and scalloping and sidewall tapering, the latter of which is clearly visible on the smaller micropillars (e.g., FIGS. 3A-3B). This tapering and scalloping were not observed for the lift-off case, but some pillars did exhibit what appeared to be a step change in width after a certain etch depth (e.g., FIGS. 1G and 1I). In the metal-break case, the scalloping appears visually similar to the scalloping effect of DRIE, but the reason for its presence in MacEtch is not readily apparent. The tapering and widening of features at the base of the etch front could be caused by a lateral shrinking of the catalyst. These defects were successfully addressed by decreasing the etchant concentration to 8.44/0.5 M/M.

As for the pillar-top erosion and porosity formation observed for metal-break but not lift-off, it is hypothesized this could be due to the available surface area for excess hole accumulation and unintended etching. When excess holes diffuse to the top of the pillars, they cause non-localized silicon oxidation, which the HF species can remove. In the case of metal-break, a polymer block exists at the top surface of the silicon feature which prevents the holes that accumulate at that surface from partaking in the oxidation and removal of silicon, thus only the holes that cause oxidation near the sidewall get etched away. The tops of the features exhibit more prominent defectivity and porosity because the unprotected sidewall top gets exposed to the etchant solution for longer. In the case of lift-off, the entire micropillar top area is exposed to the etchant and thus any holes that diffuse may distribute and get etched away more evenly from the whole top surface, thus mitigating the impact of sidewall etching and resulting in a form of electropolishing or uniform surface etching by HF alone. The improvement observed when decreasing the etchant concentration for the metal-break case could be due to the decreased number of holes being injected on the silicon, and thus mitigating porosity formation. Another possible source of porosity could be attributed to the increase in silver availability in the metal-break case as the metal catalyst that sits atop the photoresist is exposed to the etchant for a long period of time.

Metal-break, however, does have advantages over lift-off. First, performing lift-off after metal deposition leads to the concern that the released metal may redeposit elsewhere on the sample leading to unintended etching and yield-impacting defectivity, and ultrasonication of the sample for resist removal could potentially damage the metal catalyst and cause defects. These risks are removed with the metal-break process as the metal in contact with the polymer resist is not released into solution, and the sample is not subjected to ultrasonication or other mechanical perturbations. Additionally, lift-off requires that the resist have an undercut profile for metal deposition. Although this can be achieved with some forms of lithography, obtaining an undercut profile may not be possible with nanoimprint. As such, lift-off could result in metal tears or delamination if any metal is attached to the sidewall of the imprint resist. There are ways to create oxide undercuts for nanoimprint-defined features, but even this approach was presented as a means to improve metal-break rather than enable lift-off. Lastly, by relying on metal-break, fewer process steps are required for patterning of silicon. Fewer steps would require less manipulation and may decrease the risk of contaminants landing on the sample and thus improve yield.

Finally, as observed in the results presented herein, metal-break led to an increased etch rate for both etchant concentrations. With the 12.5/1 M/M solution, the etch rate increased from 1.207 (0.099) μm/min for lift-off to 1.493 (0.099) μm/min for metal-break. With the 8.44/0.5 M/M solution, on the other hand, the etch rate increased from 0.346 (0.035) μm/min to 0.756 (0.056) μm/min between lift-off and metal-break. Looking at the 3-σ CI for the metal-break sample etched using the 12.5/1 M/M solution, the mean etch rate of the lift-off sample is contained within the CI: [1.196,1.790] μm/min and thus the difference may not be statistically significant. This is not the case for the samples etched with the 8.44/0.5 M/M solution where the 3-σ CI is [0.588,0.924] μm/min.

A discussion regarding multiscale etching is now provided below. In particular, a discussion regarding the metal-break etch process is provided below.

For a given catalyst thickness, increasing the lateral etch dimension leads to a decrease in etch rate, and also can cause non-uniform etching across the lateral dimension. Non-uniformities in etching may lead to catalyst bending and strain accumulation which can cause catalyst tears, as seen in FIGS. 3A-3I. The issues with catalyst stability were addressed by decreasing the etchant concentration (see FIGS. 4A-4I), agreeing with the observation that a slower etch decreases defectivity. The difference in etch rate between scales remained, however, where using the 8.44/0.5 M/M etchant resulted in a microscale mean etch rate of 0.756 μm/min and a nanoscale mean etch rate of 1.112 μm/min. It should be noted that the 3-σ CI for the etch rate of the nanoscale samples is [0.329, 1.895] μm/min, which encompasses the mean etch rate of the microscale samples. This indicates that the difference in etch rate may not be statistically significant, though this conclusion comes with the caveat that the nanoscale etch rate had a large standard deviation due to issues with residual layer removal, as previously mentioned. Furthermore, in one embodiment, smaller features etch slower even when the process is optimized. This “inverse” ARDE (aspect ratio dependent etching) effect can be explained by the etch mechanism for MacEtch, where the diffusion driven process will be slowed down when the lateral dimension for mass transport is increased. In addition to the difference in mean etch rate for micro and nanoscale etch results, the nanoscale samples exhibited little to no etch on the microscale streets between nanopillar arrays.

In one embodiment, further process improvements were utilized to achieve a uniform etch rate for micro and nanoscale areas such that the nanopillar arrays and microscale streets etched simultaneously.

In one embodiment, such process involvements involve optimizing the catalyst thickness. Lateral penetration of the chemical species for mass transport in MacEtch appears to be at most ~700 nm. Thus, a catalyst with small pores with <700 nm spacing could lead to uniform etching of large lateral dimensions. It is possible that the 3 nm Ag and 15 nm Au catalyst stack did have pores with that spatial frequency, but these may have been too small to allow for adequate mass transport at the microscale compared to the ~100 nm lateral spacing present in the nanopillar regions. Gold is expected to remain porous until it reaches ~40 nm, but the steep etch rate decrease observed between 10 and 40 nm catalyst thickness does show that pore size plays an important role in mass transport. Furthermore, the 3 nm Ag layer is not expected to form a continuous film. Therefore, in one embodiment, the optimization of catalyst thickness is focused on changing the thickness of the gold layer such that the reaction could take place through pores in the film rather than at the edges of the defined patterns, and that the transport through these pores occurs at a similar rate as that of the nanopillar arrays to achieve uniform etch at the micro and nanoscales. At 12 nm, the microscale streets were etched slower than the nanopillar regions, whereas decreasing it to 10 nm caused a large amount of nanowhiskers to form in the streets, indicative of large pores on the catalyst.

Using an 11 nm Au layer, however, led to uniform etch across the nanopillar array and microscale streets, despite some defects still present on some areas of the sample (see FIG. 6E). Additionally, a longer plasma etch was attempted with the 3 nm Ag and 11 nm Au layer, but no significant improvements were observed, and defects were still present.

As a result, in one embodiment, a shorter plasma etch time of 55 seconds was utilized, which was the same amount of time used for the individual nanoscale experiments.

Overall, the optimized catalyst thickness and lower concentration etchant yielded good etch uniformity across large areas with low defectivity at both the micro and nanoscales simultaneously with a mean etch rate of 1.793 μm/min, which exceeded the mean etch rate for both micro and nanoscale individual experiments (0.756 μm/min at the microscale, and 1.112 μm/min at the nanoscale). This increase in etch rate can be attributed to the decreased metal thickness improving mass transport during etch. The results obtained achieved an aspect ratio of ~18:1, without substantial amounts of collapse.

In one embodiment, metal assisted chemical etching is performed where the etched patterns are sub-10 μm, sub-1 μm, sub-750 nm, sub-500 nm, sub-300 nm, sub-200 nm, sub-100 nm, sub-50 nm, sub-30 nm, sub-20 nm, or sub-10 nm in feature size. In one embodiment, the etched patterns are adjacent to a second set of etched patterns that are over-100 nm, over-200 nm, over-500 nm, over-750 nm, over-1 μm, over-5 μm, over-10 μm, over-20 μm, over-30 μm, over-40 μm, over-50 μm, or over-100 μm in feature size. In a separate embodiment, only a single set of etched patterns are present, where the feature size in the patterns is over-100 nm, over-200 nm, over-500 nm, over-750 nm, over-1 μm, over-5 μm, over-10 μm, over-20 μm, over-30 μm, over-40 μm, over-50 μm, or over-100 μm. In one embodiment, one or two sets of the etched patterns are etched in a single etching step, with etch non-uniformity of less than sub-50 nm per micrometer of etch, sub-25 nm per micrometer of etch, sub-10 nm per micrometer of etch, sub-5 nm per micrometer of etch, sub-1 nm per micrometer of etch, or sub-100 nm per micrometer of etch. In one embodiment, the etch uniformity spec is enabled by a multi-layered catalyst utilized in the MacEtch.

As a result of the foregoing, MacEtch-enabled micro and nanoscale etching of silicon with feature size variation from 100 nm to 100 μm for the first time. Simultaneous micro and nanoscale etching is demonstrated by using a catalyst bilayer consisting of 3 nm Ag and 11 nm Au with an etchant bath with 8.44 M HF and 0.5 M H₂O₂. Based on the measurements obtained, the pillars have an average AR of 18:1 and were etched at a rate of approximately 1.8 μm/min. This is the first demonstration of multiscale MacEtch for feature size variation by three orders of magnitude without any ARDE effects, significant etch lag as the scale changes, or nanowhisker-type defect formation in the microscale etch areas. Furthermore, the multiscale etching results discussed herein illustrate achieving an etch rate that is 5 times larger than the multiscale MacEtch results of other techniques, though the aspect-ratio is lower. Furthermore, in one embodiment, the gold layer thickness is decreased which leads to porosity-induced defects in the microscale areas, whereas increasing gold thickness causes etch rate disparity between nanoscale and microscale areas. Additionally, dependence of etchant concentration on etch quality is clearly shown at the microscale, and the need for a slow etch to accomplish higher quality features is validated experimentally regardless of pre-treatment of the sample prior to the etch (i.e., metal-break or lift-off).

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method for metal assisted chemical etching, the method comprising:
patterning a catalyst layer on a surface of a semiconducting material, wherein said catalyst layer comprises a pattern of sub-100 nm or less than sub-100 nm features adjacent to over 1 μm-sized features, wherein said catalyst layer is multi-layered; and
exposing said patterned catalyst layer to an etchant, wherein said patterned catalyst layer causes etching of said semiconducting material to form nanostructures;
wherein a non-uniformity of said etch is sub-50 nm per 1 μm of etch, wherein said non-uniformity is enabled by said multi-layered catalyst.

2. The method as recited in claim 1, wherein said catalyst layer comprises a pattern of sub-100 nm features adjacent to over 10 μm-sized features.

3. The method as recited in claim 1, wherein said catalyst layer comprises a pattern of sub-100 nm features adjacent to over 100 μm-sized features.

4. The method as recited in claim 1, wherein said catalyst layer comprises a pattern of sub-50 nm features adjacent to over 1 μm-sized features.

5. The method as recited in claim 1, wherein said catalyst layer comprises a pattern of sub-50 nm features adjacent to over 10 μm-sized features.

6. The method as recited in claim 1, wherein said catalyst layer comprises a pattern of sub-50 nm features adjacent to over 100 μm-sized features.

7. The method as recited in claim 1, wherein said catalyst layer comprises a pattern of adjacent features that are different in their sizes by three-orders of magnitude.

8. The method as recited in claim 1, wherein said catalyst layer comprises a bilayer of silver and gold.

9. The method as recited in claim 8, wherein said silver has a thickness of around 3 nm, wherein said gold has a thickness of around 11 nm.

10. The method as recited in claim 1, wherein said etchant comprises a concentration of HF between 5 and 10M, wherein said etchant further comprises a concentration of H₂O₂ between 0.4 and 0.6M.

11. The method as recited in claim 1, wherein said etchant comprises a concentration of HF of 8.4M, wherein said etchant further comprises a concentration of H₂O₂ of 0.5M.

12. A method for metal assisted chemical etching, the method comprising:
patterning a substrate with lithographic structures, wherein a surface of said substrate is exposed in areas without said lithographic structures, wherein said patterning of said substrate with lithographic structures results in sub-100 nm features adjacent to over 1 μm-sized features on said substrate;
depositing a catalyst on said exposed substrate surface, wherein said catalyst is a multi-layered catalyst; and
exposing said deposited catalyst layer to an etchant, wherein said deposited catalyst layer causes etching of semiconducting material of said substrate to form nanostructures;
wherein non-uniformity of said etch is sub-50 nm per 1 μm of etch, wherein said non-uniformity is enabled by said multi-layered catalyst.
